(19) United States
(12) Patent Application Publication
(10) Pub. No.: US 2013/0003275 A1
(43) Pub. Date: Jan. 3, 2013

(54) RECORDING TAPE CARTRIDGE

(75) Inventors: Yosuke Sumiya, Kanagawa (JP); Kazuo Hiraguchi, Kanagawa (JP)

(73) Assignee: FUJIFILM CORPORATION, Minato-ku, Tokyo (JP)

(21) Appl. No.: 13/634,241

(22) PCT Filed: Feb. 4, 2011
(86) PCT No.: PCT/JP2011/052432

§ 371 Date: Sep. 12, 2012

(30) Foreign Application Priority Data
Mar. 16, 2010 (JP) 2010-059947

(51) Int. Cl. H05K 5/02

(52) U.S. Cl. 361/679.01

(57) ABSTRACT

Disclosed is a recording tape cartridge for which the communications performance of the security tag is not reduced at least when the recording tape cartridge case is stacked on top of other recording tape cartridge cases. The recording tape cartridge (10) comprises a case (12), which houses a reel (20) around which a recording tape (T) is wound and a security tag (110) that can transmit and receive externally, which is located inside the case (12). The security tag (110) is columnar with a coil formed by wire material wound around the outer peripheral surface of a magnetic core. The security tag (110) is disposed within the case (12) in a manner such that security tags (110) within cases (12) of other recording tape cartridges (10) and the axis (P) are not superposed.

### TECHNICAL FIELD

The present invention relates to a recording tape cartridge having a reel on which a recording tape, such as a magnetic tape or the like, is wound, and more particularly, relates to a recording tape cartridge equipped with a security function.

### BACKGROUND ART

Recording tape cartridges are conventionally known in which a recording tape such as a magnetic tape or the like is wound on a reel, and that singly accommodate this reel within a case. Because this recording tape cartridge is often used as a data recording/playback medium (data backup) for computers or the like, there are cases in which security measures for theft prevention are applied thereto.

For example, a security tag, that can transmit and receive to and from the exterior, is provided within the case of a recording tape cartridge such that, when the recording tape cartridge is transported-out from a predetermined security area, an alarm sound is issued from a security gate or the like that is provided at the entrance/exit of that security area, and theft of the recording tape cartridge is psychologically prevented (see, for example, Patent Document 1).
Patent Document 1: Japanese Patent Application Laid-Open No. 2009-129531

### DISCLOSURE OF THE INVENTION

### Technical Problem

However, the security tag disclosed in Patent Document 1 is made to be a cylindrical shape equipped with a coil that is formed by winding a wire material around the outer peripheral surface of a magnetic core, and is accommodated and set within a housing container such that the axial center thereof is perpendicular to the bottom plate of the case. Therefore, when the case of the recording tape cartridge is stacked with the case of another recording tape cartridge, magnetic coupling arises at the security tags that are set within the respective cases, and there is the drawback that the communication performance of the security tag deteriorates.

Thus, in consideration of the above-described circumstances, an object of the present invention is to provide a recording tape cartridge that can make it such that the communication performance of a security tag does not deteriorate at least when the case of the recording tape cartridge is stacked with the case of another recording tape cartridge.

### Solution to Problem

In order to achieve the above-described object, a recording tape cartridge of a first aspect relating to the present invention includes: a case that accommodates a reel on which a recording tape is wound; and a security tag that is provided within the case and can transmit and receive to and from an exterior, wherein the security tag is made to be a columnar shape having a coil that is formed by a wire material being wound around an outer peripheral surface of a magnetic core, and is set within the case such that, when the case is stacked with a case of another recording tape cartridge, an axial center does not overlap with a security tag within the case of the other recording tape cartridge.

In accordance with the above-described aspect, even if the case of the recording tape cartridge is stacked with the case of another recording tape cartridge, magnetic coupling does not arise at the security tags that are set within the respective cases. Accordingly, the communication performance of the security tag does not deteriorate.

Further, in a recording tape cartridge of a second aspect relating to the present invention, in the recording tape cartridge of the above-described aspect, the security tag is set such that the axial center is not perpendicular to a bottom plate of the case.

In accordance with the above-described aspect, even if the case of the recording tape cartridge is stacked with the case of another recording tape cartridge, magnetic coupling does not arise at the security tags that are set within the respective cases. Accordingly, the communication performance of the security tag does not deteriorate.

Further, in a recording tape cartridge of a third aspect relating to the present invention, in the recording tape cartridge of the above-described aspect, the security tag is set such that the axial center is substantially parallel to a bottom plate of the case.

In accordance with the above-described aspect, even if the case of the recording tape cartridge is stacked with the case of another recording tape cartridge, magnetic coupling does not arise at the security tags that are set within the respective cases. Accordingly, the communication performance of the security tag does not deteriorate.

Further, in a recording tape cartridge of a fourth aspect relating to the present invention, in the recording tape cartridge of the above-described aspect, the security tag is set such that the axial center is not perpendicular to a peripheral wall of the case, as seen from an axial direction of the reel.

In accordance with the above-described aspect, even if the case of the recording tape cartridge is lined-up in the left-right direction or the front-back direction with the case of another recording tape cartridge, magnetic coupling does not arise at the security tags that are set within the respective cases. Accordingly, the communication performance of the security tag does not deteriorate.

Further, in a recording tape cartridge of a fifth aspect relating to the present invention, the recording tape cartridge of the above-described aspect includes: a holding member that is provided within the case, and at whose one end side is formed a holding portion that, in cooperation with the case, holds the security tag from an axial direction of the reel and a direction orthogonal to the axial direction; and a fitted-together portion that is formed within the case, and with which a fit-together portion, that is formed at another end side of the holding member, is fit-together.

In accordance with the above-described aspect, the holding portion, that is formed at the holding member, holds, in cooperation with the case, the security tag from the axial direction of the reel and a direction perpendicular to this axial direction. Namely, this holding member only contacts the security tag from the axial direction of the reel and a direction perpendicular to this axial direction. Accordingly, this holding member can hold the security tag even if the shape of the security tag is changed, and the degrees of freedom in design of the security tag can be improved.

Further, in a recording tape cartridge of a sixth aspect relating to the present invention, in the recording tape cartridge of the above-described aspect, the holding member is formed so as to be able to be installed within the case, in a state in which the security tag is provided within the case.

In accordance with the above-described aspect, even if the shape of the security tag is changed, the holding member can be installed. Accordingly, the degrees of freedom in design of the security tag can be improved.

Further, a recording tape cartridge of a seventh aspect relating to the present invention includes: a case that is substantially rectangular and that accommodates a reel on which a recording tape is wound; and a security tag that is provided within the case and can transmit and receive to and from an exterior, wherein the security tag is made to be a columnar shape having a coil that is formed by a wire material being wound around an outer peripheral surface of a magnetic core, and is set within the case such that, when the case is lined-up adjacent to a case of another recording tape cartridge with front and rear, or left and right, peripheral walls being aligned, an axial center does not overlap with a security tag within the case of the other recording tape cartridge.

In accordance with the above-described aspect, even if the case of the recording tape cartridge is lined-up adjacent to a case of another recording tape cartridge with front and rear, or left and right, peripheral walls being aligned, magnetic coupling does not arise at the security tags that are set within the respective cases. Accordingly, the communication performance of the security tag does not deteriorate.

### Advantageous Effects of Invention

As described above, in accordance with the present invention, there can be provided a recording tape cartridge that can make it such that the communication performance of a security tag does not deteriorate at least when the case of the recording tape cartridge is stacked with the case of another recording tape cartridge.

### BRIEF DESCRIPTION OF DRAWINGS

FIG. 1 is a schematic perspective view of a recording tape cartridge.

FIG. 2 is a schematic exploded perspective view when viewing the recording tape cartridge from above.

FIG. 3 is a schematic exploded perspective view when viewing the recording tape cartridge from below.

FIG. 4 is a schematic plan view of a lower case in which a security tag is disposed laterally.

FIG. 5 is a schematic sectional view showing a state in which cases, in which security tags are disposed laterally, are stacked.

FIG. 6 is a schematic perspective view of a holding member.

FIG. 7 is a schematic plan view of the holding member.

FIG. 8 is a schematic bottom view of the holding member.

FIG. 9 is a schematic sectional view of a fit-together portion at the holding member.

FIG. 10 is a schematic perspective view of the lower case, showing the holding member that holds the security tag that is disposed laterally.

FIG. 11 is a schematic plan view of the lower case, showing the holding member that holds the security tag that is disposed laterally.

FIG. 12 is a schematic sectional view of the lower case, showing the holding member that holds the security tag that is disposed laterally.

FIG. 13 is a schematic perspective view of the lower case in which the security tag is disposed obliquely with respect to the vertical direction.

FIG. 14 is a schematic plan view of the lower case in which the security tag is disposed obliquely with respect to the vertical direction.

FIG. 15 is a schematic sectional view showing a state in which cases, in which security tags are disposed obliquely with respect to the vertical direction, are stacked.

### BEST MODES FOR CARRYING OUT THE INVENTION

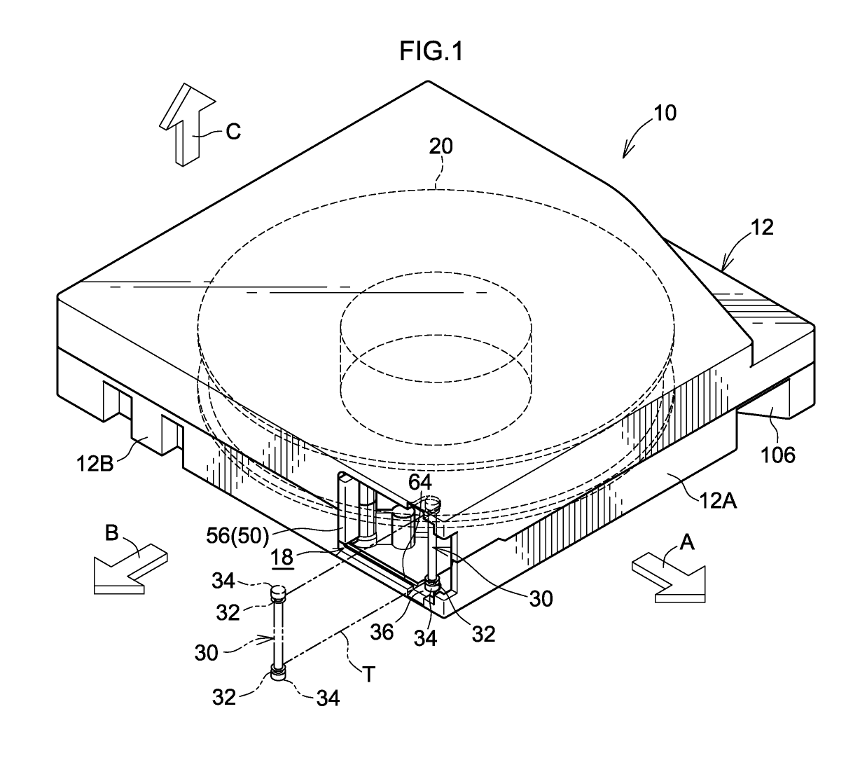

Embodiments of the present invention will be described in detail hereinafter on the basis of the examples shown in the drawings. Note that, for convenience of explanation, in FIG. 1, the direction of loading a recording tape cartridge 10 into a drive device is denoted by arrow A, and this is the forward direction (front side) of the recording tape cartridge 10. Further, the direction of arrow B, that is orthogonal to arrow A, is the rightward direction (right side). Moreover, the direction orthogonal to the direction of arrow A and the direction of arrow B is denoted by arrow C, and this is the upward direction (top side) of the recording tape cartridge 10. First, the schematic structure of the recording tape cartridge 10 will be described.

As shown in FIG. 1 through FIG. 3, the recording tape cartridge 10 has a case 12 that is substantially shaped as a rectangular box. This case 12 is structured by an upper case 14 and a lower case 16, that are made of a resin such as polycarbonate (PC) or the like, being joined together by screws in a state in which a peripheral wall 14B, that stands erect at the peripheral edge of a ceiling plate 14A, and a peripheral wall 16B, that stands erect at the peripheral edge of a bottom plate 16A, are abutting one another respectively.

Namely, screw bosses 15 are formed in vicinities of the respective corner portions of the upper case 14 and the lower case 16, and the case 12 is assembled by unillustrated screws being screwed-together with these screw bosses 15 from the bottom surface side of the lower case 16. Further, a single reel 20 is rotatably accommodated within the case 12.

This reel 20 is structured by a reel hub 22, that is shaped as a cylindrical tube having a bottom and that structures the axially central portion, and a lower flange 26, that is provided at the lower end portion thereof, being molded integrally, and an upper flange 24 being ultrasonically welded to the top end portion of the reel hub 22. Further, a recording tape T, such as a magnetic tape or the like that serves as an information recording/playback medium, is wound on the outer peripheral surface of this reel hub 22, and the width direction end portions of the wound recording tape T are held by the upper flange 24 and the lower flange 26.

Moreover, a reel gear 44 is formed in an annular shape at the bottom surface (outer surface) of a bottom wall (bottom portion) 28 of the reel hub 22. A gear opening 40, that is for exposing this reel gear 44 to the exterior, is formed in the central portion of the lower case 16. Due to the reel gear 44, that is exposed from this gear opening 40, meshing-together with a driving gear (not shown) formed at a rotating shaft (not shown) of a drive device and being rotated and driven thereby, the reel 20 can rotate relative to the case 12 within the case 12.

A reel plate 46, that is an annular metal plate formed of a magnetic material, is fixed integrally and coaxially by insert molding to the radial direction inner side of the reel gear 44, at the bottom surface of the bottom wall 28. The reel plate 46 is attracted to/held by the magnetic force of an annular magnet (not shown) that is provided at the rotating shaft of the drive device.

Further, the reel 20 is held so as to not joggle by play restricting walls 42 that are provided to project-out partially at the inner surface of the ceiling plate 14A of the upper case 14 and the inner surface of the bottom plate 16A of the lower case 16 respectively, and that serve as inner walls that are on a circular locus that is coaxial with the gear opening 40 and that restrict the accommodation area of the reel 20.

Moreover, an opening 18, that is for the pulling-out of the recording tape T wound on the reel 20, is formed in a right wall 12B of the case 12. A leader pin 30, that serves as a leader member that is operated to be pulled-out while being anchored (engaged) by a pull-out member (not shown) of the drive device, is fixed to the free end portion of the recording tape T that is pulled-out from this opening 18. Further, annular grooves 32 are formed in both end portions of the leader pin 30, that project-out further than the width direction end portions of the recording tape T. These annular grooves 32 are anchored by hooks or the like of the pull-out member.

Further, a pair of upper and lower pin holding portions 36, that position and hold the leader pin 30 within the case 12, are provided at the inner side of the opening 18 of the case 12, i.e., at the inner surface of the ceiling plate 14A of the upper case 14 and the inner surface of the bottom plate 16A of the lower case 16. These pin holding portions 36 form substantially semicircular shapes whose recording tape T pull-out sides are open. Both end portions 34 of the leader pin 30, that is in an upright state, can enter into and exit from the pin holding portions 36 from these open sides.

Moreover, a plate spring 38 is fixedly disposed in a vicinity of the pin holding portions 36. Bifurcated distal end portions of this plate spring 38 respectively engage the upper and lower both end portions 34 of the leader pin 30, and hold the leader pin 30 at the pin holding portions 36. Note that this is a structure in which, when the leader pin 30 is to enter into or exit from the pin holding portions 36, the distal end portions of the plate spring 38 elastically deform appropriately so as to permit movement of the leader pin 30.

Further, the opening 18 is opened and closed by a door 50. This door 50 is formed in the shape of a substantially rectangular plate of a size that can close the opening 18. Groove portions 64, into which the upper and lower end portions of the door 50 are slidably fit, are formed in the ceiling plate 14A and the bottom plate 16A at the inner side of the opening 18, such that the door 50 can move along the right wall 12B of the case 12.

Moreover, a shaft 52 is provided to project at the center of the rear end portion of the door 50, and a coil spring 58 is fit around this shaft 52. Further, a widening portion 54, that prevents this coil spring 58 from falling-off, is formed at the rear end of the shaft 52. Moreover, a supporting stand 60, that has an anchor portion 62 that anchors the rear end of the coil spring 58 that is fit on this shaft 52, is provided to project at the lower case 16.

Accordingly, the door 50 is a structure that, due to the shaft 52 being supported so as to be freely slidable on the supporting stand 60, and the rear end of the coil spring 58 being anchored on the anchor portion 62, is always urged in the direction of closing the opening 18 by the urging force of this coil spring 58. Note that it is preferable that a supporting stand 66, that supports the shaft 52 when the opening 18 is open, be further provided at the rear side of the supporting stand 60 so as to project-out.

Further, a convex portion 56 for opening/closing operation is provided to project outwardly from the front end portion of the door 50. This convex portion 56 engages with an opening/closing member (not shown) of the drive device as the recording tape cartridge 10 is loaded into the drive device. Due thereto, the door 50 is a structure that is opened against the urging force of the coil spring 58.

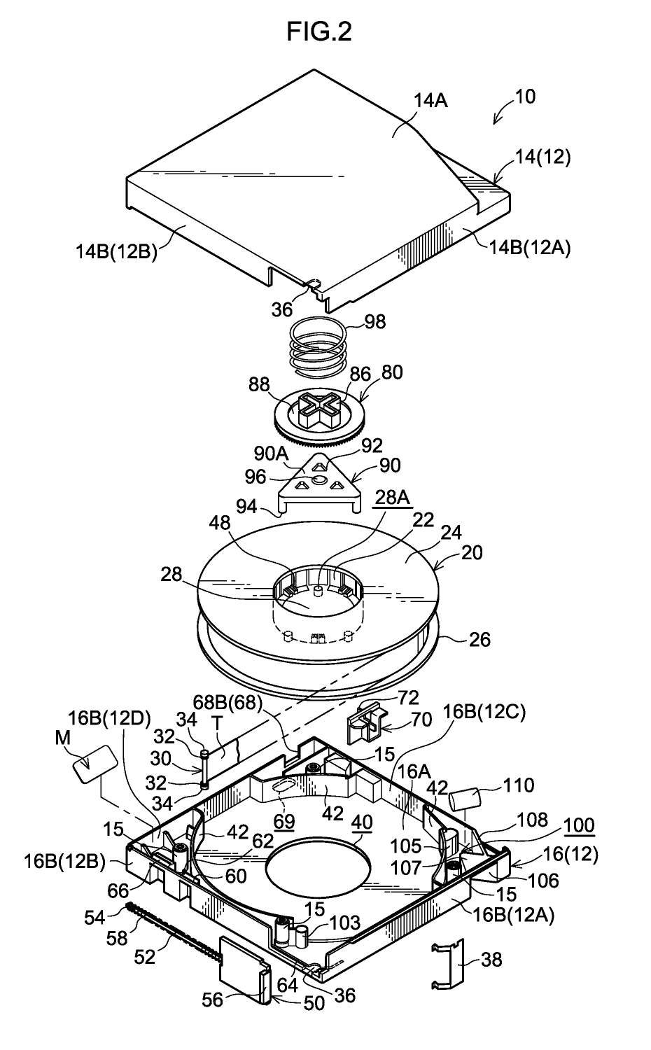

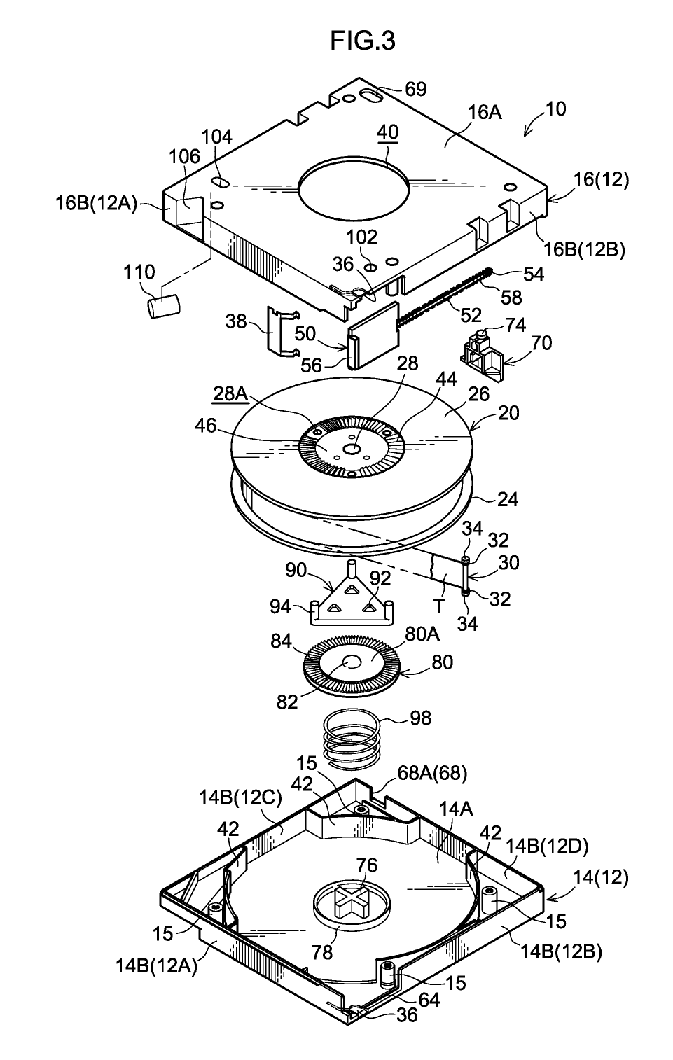

Moreover, as shown in FIG. 2 and FIG. 3, a write protect 70, by which recording onto the recording tape T is set to be possible/impossible, is provided so as to be able to slide in the left-right directions at the rear left portion of the case 12. A hole 68, through which protrudes an operation projection 72 for manually operating this write protect 70, is formed in a rear wall 12D of the case 12. This hole 68 is a structure that is formed by a cut-out portion 68A, that is formed in the peripheral wall 14B of the upper case 14, and a cut-out portion 68B, that is formed in the peripheral wall 16B of the lower case 16, when the upper case 14 and the lower case 16 are joined together.

Still further, a long hole 69, through which a protrusion 74 of the write protect 70 is exposed, is formed in the bottom plate 16A of the lower case 16, so as to be long in the left-right direction. When the recording tape cartridge 10 is loaded in a drive device, the position of the write protect 70 is sensed at this drive device side, and it is automatically judged whether recording onto the recording tape T is possible/impossible. Note that this protrusion 74 does not project-out from the bottom surface of the bottom plate 16A of the lower case 16. Further, as shown in FIG. 2, a memory board M, in which is stored various types of information such as the recording capacity, the recording format and the like, is disposed at the rear right portion of the case 12 at a predetermined angle of inclination (e.g., 45°).

Moreover, as shown in FIG. 2 and FIG. 3, plural (e.g., three at intervals of 120°) engaging gears 48 stand erect at the peripheral edge of the top surface of the bottom wall 28 of the reel hub 22 so as to be spaced apart at predetermined intervals (uniform intervals). Plural (in this case, three at intervals of 120°) through-holes 28A are formed at predetermined positions on the reel gear 44, between these engaging gears 48. Further, a circular-plate-shaped braking member 80 molded of a resin material is inserted within this reel hub 22.

A braking gear 84, that can mesh with the engaging gears 48, is formed in an annular shape at the peripheral edge of a bottom surface 80A of the braking member 80. An engaging projection 86, that is substantially cross-shaped in plan view and into which is inserted a rotation restricting rib 76 that is substantially cross-shaped in plan view and that is provided to project-out downward from the inner surface of the ceiling plate 14A of the upper case 14, stands erect at the top surface of the braking member 80 so as to be slightly taller than the height of this rotation restricting rib 76. Due thereto, the braking member 80 can be made unable to rotate with respect to the case 12 (the upper case 14), and can move in vertical directions within the reel hub 22.

Further, a compression coil spring 98 is disposed between the upper case 14 and the braking member 80. Namely, one end of the compression coil spring 98 abuts the inner side (between the rotation restricting rib 76 and an annular projection 78) of the annular projection 78 that is provided to project at the outer side of the rotation restricting rib 76 of the upper case 14, and the other end is disposed in a state of abutting the interior of an annular groove 88 that is provided in the top surface of the braking member 80. The braking member 80 is always urged downward by the urging force of this compression coil spring 98.

Accordingly, when the recording tape cartridge 10 is not in use (is not loaded in a drive device), the braking gear 84 is always in a state of meshing-together with the engaging gears 48, and the reel 20 is in a rotation locked state in which rotation thereof relative to the case 12 is impeded. Note that, at this time, the reel 20 is pushed against the lower case 16 side by this urging force, and the reel gear 44 is exposed from the gear opening 40.

Further, a releasing member 90, that is molded of a resin material and is substantially triangular in plan view, is inserted within the reel hub 22 at the lower side of the braking member 80 (between the bottom wall 28 and the braking member 80). Plural (three in the illustrated structure) through-holes 92, that are formed in predetermined shapes at appropriate positions, are formed in the releasing member 90, and lightening of the weight of the releasing member 90 is devised. Further, leg portions 94, that are inserted through the through-holes 28A and project-out a predetermined height above the reel gear 44 from the bottom surface of the bottom wall 28, are provided to project at the bottom surface and the respective vertex portions of the releasing member 90.

Moreover, a supporting convex portion 96 that is planar is formed at the center of a top surface 90A of the releasing member 90, and a substantially hemispherical releasing protrusion 82, that is provided to project-out at the center of the bottom surface 80A of the braking member 80, abuts the supporting convex portion 96 (see FIG. 2 and FIG. 3). Due thereto, there is a structure in which the surface area of contact between the braking member 80 and the releasing member 90 is reduced, and the sliding resistance at the time of use (when the reel 20 rotates) is lessened.

Further, holes 102, 104 for positioning, into which positioning members (not illustrated) provided at the drive device are inserted when the recording tape cartridge 10 is loaded in the drive device, are formed (see FIG. 3) so as to be apart from one another in the left-right direction at the front wall 12A side of the bottom surface of the bottom plate 16A of the lower case 16.

The hole 102 at the right side is formed in a substantially circular shape, and the hole 104 at the left side is formed in a substantially oval shape that is long in the left-right direction. Due thereto, there is a structure in which, even if the recording tape cartridge 10 is loaded in the drive device so as to be offset slightly in the left-right direction, these positioning members are reliably inserted, and there is a structure in which this positional offset is corrected. Further, bag portions 103, 105, that serve as bosses that structure these holes 102, 104, are formed at the inner surface of the bottom plate 16A of the lower case 16 in convex shapes (shapes of protrusions) that protrude toward the upper case 14 side (see FIG. 2).

Further, a recess 106 that is substantially V-shaped in bottom view is formed in the front wall 12A (the peripheral wall 16B) at the front side of the hole 104 (the bag portion 105) of the lower case 16 (see FIG. 1 through FIG. 3). When the recording tape cartridge 10 is loaded in a drive device, a position restricting member (not shown) provided at this drive device engages with this recess 106, and due thereto, the position of the recording tape cartridge 10 in the loading direction is restricted.

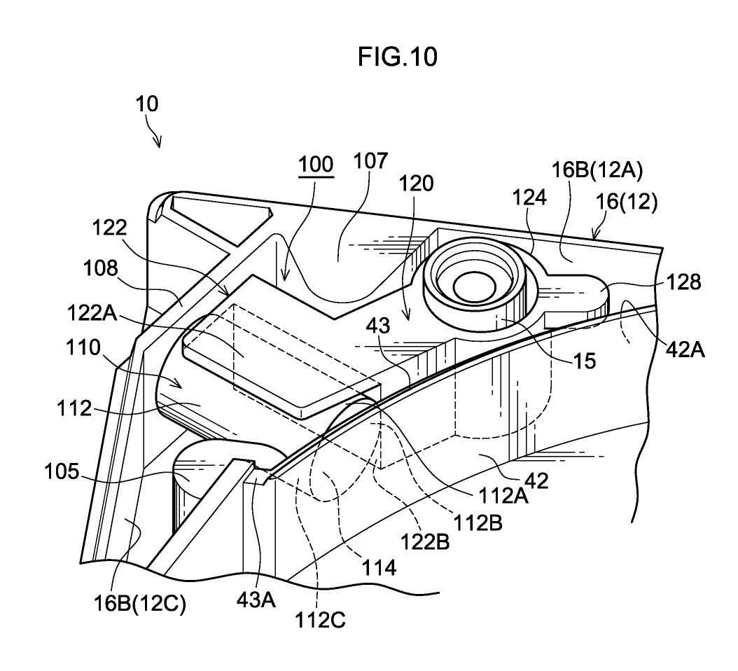

Moreover, a jutting-out wall portion 107, that is substantially triangular in plan view and juts-out toward the rear, is formed at the inner surface of this front wall 12A (the peripheral wall 16B) by structuring the recess 106 (see FIG. 2). Further, a standing wall 108 of the same height is provided continuously and integrally, so as to head diagonally rearward and leftward, at the left side wall of this jutting-out wall portion 107. This standing wall 108 is provided continuously and integrally and at the same height also with a left wall 12C (the peripheral wall 16B) of the lower case 16 (see FIG. 10).

Further, the space, that is substantially surrounded by this standing wall 108, the peripheral wall 16B that is provided continuously from this standing wall 108, the jutting-out wall portion 107, the screw boss 15 at the front left corner portion of the case 12, the play restricting wall 42 and the bag portion 105, is a setting space 100. A security tag 110 that will be described later is disposed within this setting space 100.

Here, the security function that is added to the recording tape cartridge 10 will be described next. Namely, the security tag 110, that is provided within the case 12 of this recording tape cartridge 10 in order to prevent the recording tape cartridge 10 from being transported-out from a predetermined security area, will be described.

Note that this security tag 110 is disposed at a determined position within the setting space 100 that is formed at the front left corner portion (corner portion) of the case 12, and this position does not fluctuate greatly per recording tape cartridge 10. Namely, the security tags 110 are disposed at substantially the same positions within the respective recording tape cartridges 10.

The security tag 110 is structured overall in the shape of a solid cylinder, and has a solid-cylindrical magnetic core at whose both end portions flanges are formed, and a coil that is formed by winding a wire member around the outer peripheral surface that is sandwiched by the respective flanges at the magnetic core (see FIG. 2 through FIG. 5, FIG. 10 through FIG. 15). Further, lead terminals of capacitors (not illustrated) are connected in parallel to the both ends of the winding, and are structured so as to be able to transmit and receive to and from an emitting antenna and a receiving antenna (the exterior) that are provided at a security gate (not shown) of a security area.

Namely, when the recording tape cartridge 10, in which this security tag 110 is incorporated, passes through a security gate that is disposed so as to oppose the entrance/exit of the security area, radio waves are transmitted and received between the emitting antenna and the receiving antenna that are provided at this security gate, and the security tag 110 that is provided within the case 12 of the recording tape cartridge 10, and the fact that the recording tape cartridge 10 has been transported-out of the security area is sensed.

Accordingly, if there is a system that emits an alarm sound or the like from this security area (the security gate or the like) due to this sensing, theft or inadvertent taking-out (transporting-out) of the recording tape cartridge 10 can be psychologically prevented. Note that, although the security tag 110 relating to the present embodiment is formed in a solid-cylindrical shape, it is not limited to this, and, provided that the security tag is formed in the shape of a column (the shape of a rod), the security tag may be formed, for example, in the shape of a prism, the shape of a cylindrical tube, or the like.

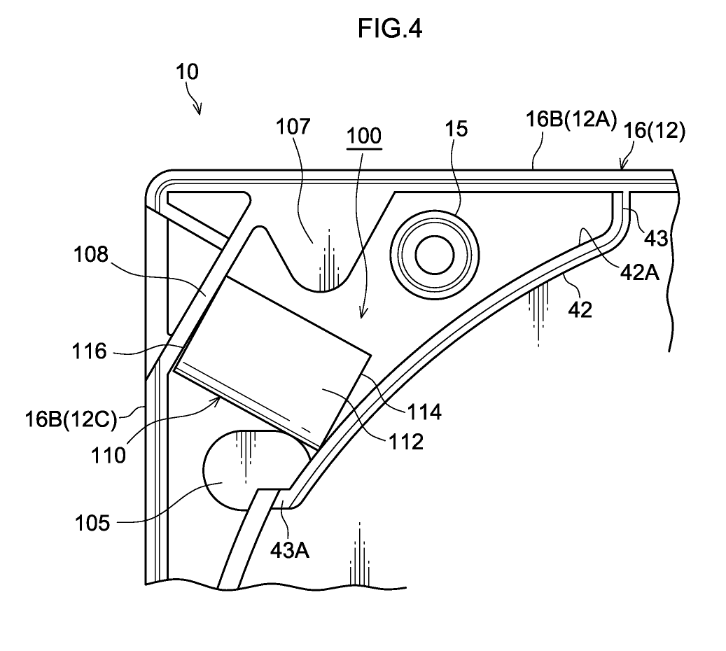

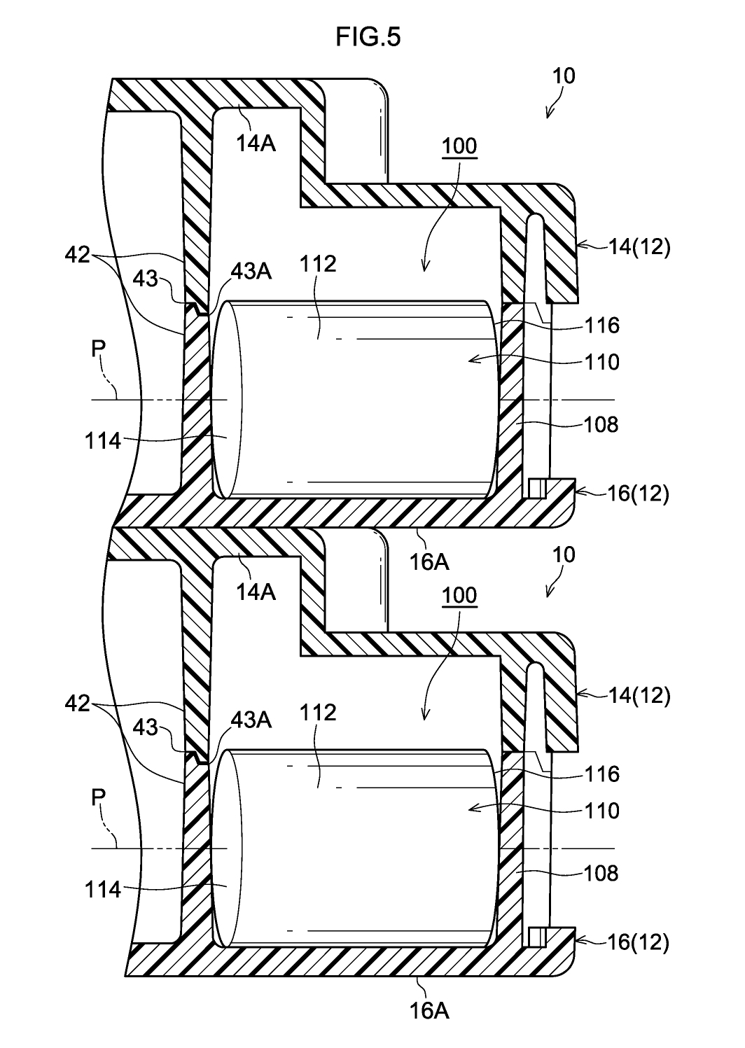

Further, this security tag 110 is set within the setting space 100 such that an axial center P (shown by the imaginary line in FIG. 5) is not perpendicular to the bottom plate 16A of the lower case 16. More concretely, as shown in FIG. 4, this security tag 110 is disposed laterally within the setting space 100 such that the axial center P is substantially parallel to the bottom plate 16A of the lower case 16.

Accordingly, as shown in FIG. 5, even if the case 12 of the recording tape cartridge 10 is stacked with the case 12 of the other recording tape cartridge 10 in the vertical direction (the height direction, the axial direction of the reel 20), the axial centers P of the security tags 110 set within the respective cases 12 do not overlap one another, and magnetic coupling does not arise at the respective security tags 110.

Further, in the plan view shown in FIG. 4 (seen from the axial direction of the reel 20), this security tag 110 is set such that the axial center P is not perpendicular to the peripheral wall 16B of the lower case 16 (such that the axial center P is not orthogonal to the front wall 12A and the left wall 12C of the case 12).

Accordingly, even if the case 12 of the recording tape cartridge 10 is lined-up adjacent to the case 12 of the other recording tape cartridge 10 with the front walls 12A and the rear walls 12D, or with the left walls 12C and the right walls 12B, aligned, the axial centers P of the security tags 110 set within the respective cases 12 do not overlap one another, and magnetic coupling does not arise at the respective security tags 110.

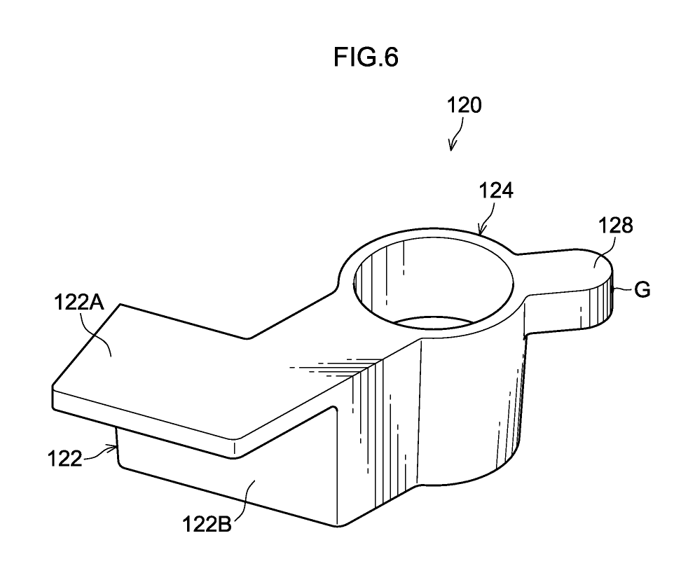

Further, this security tag 110 may be made to be a structure that is held by a holding member 120, that is made of resin and shown in FIG. 6 through FIG. 12, and that is fixed such that the position of the security tag 110 does not fluctuate per recording tape cartridge 10. This holding member 120 has, at one end side, a holding portion 122 that holds the security tag 110, and has, at the other end side, a fit-together portion 124 that is mounted to the case 12 (the lower case 16).

The fit-together portion 124 is formed in the shape of a cylindrical tube that is insertingly-fit (fit-together) by press-fitting from above with the screw boss 15 that serves as a fitted-together portion and is provided to project at the inner surface of the bottom plate 16A of the lower case 16. Namely, as shown in detail in FIG. 6 through FIG. 9, a jutting-out portion 126, that is substantially flat-plate-shaped and whose upper portion side juts-out more toward the radial direction inner side than the lower portion side, is formed at a portion of the inner peripheral surface of this fit-together portion 124. Due to this jutting-out portion 126, the inner diameter of a portion of the fit-together portion 124 is structured to be smaller than the inner diameter of the other region.

Accordingly, due to this jutting-out portion 126, the screw boss 15 is a structure that is press-fit (fit-together with resistance) into the fit-together portion 124. Due thereto, the fit-together portion 124 coming-off from the screw boss 15 (moving upward) is prevented, and rotation of the fit-together portion 124 (the holding member 120) around the screw boss 15 is suppressed or prevented.

On the other hand, the holding portion 122 is made to be a shape having a flat wall portion that can push and hold the security tag 110 that is disposed within the setting space 100 of the lower case 16, from the upper side (the axial direction of the reel 20) and the lateral side (the direction orthogonal to the axial direction of the reel 20: hereinafter called the “horizontal direction” upon occasion).

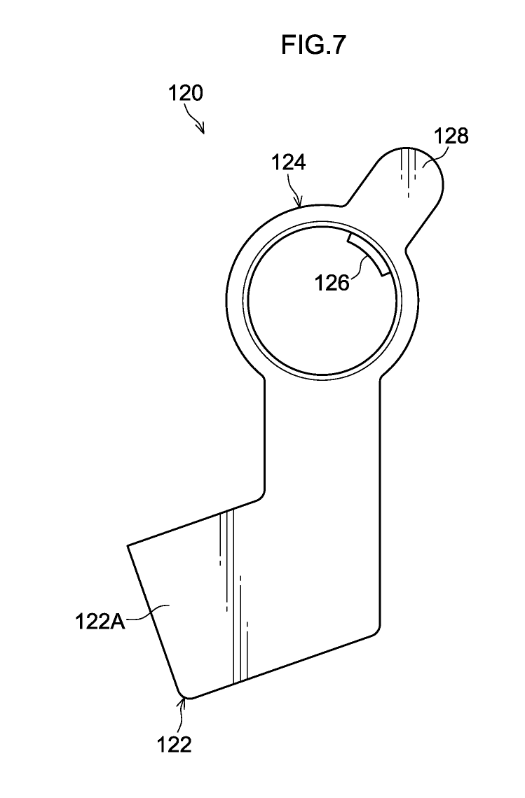

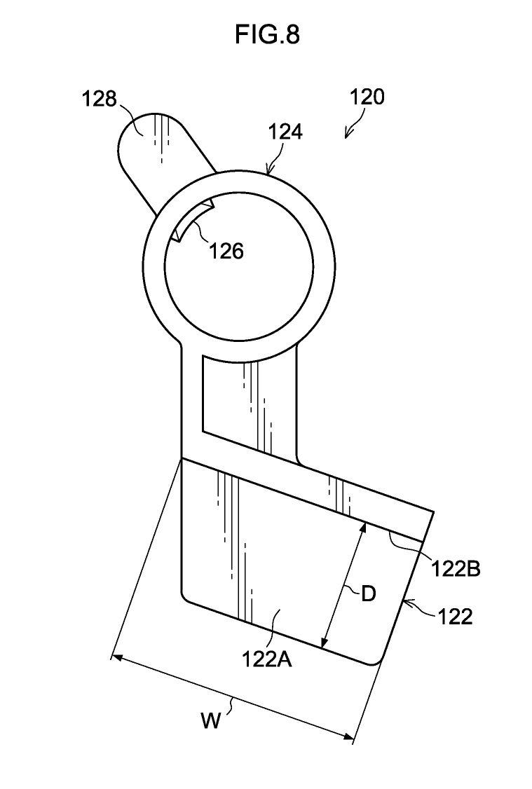

Namely, this holding portion 122 has a pressing portion 122A that, as shown in FIG. 6 and FIG. 7, is flat-plate-shaped and extends, from the top end portion of the outer peripheral surface of the fit-together portion 124, integrally in a substantial “J” shape in plan view that has a wide width, and is provided with a wall surface that faces downward, and a pushing portion 122B that, as shown in FIG. 6 and FIG. 8, is flat-plate-shaped and extends integrally (integrally with the pressing portion 122A as well) in a substantial “L” shape in bottom view, at the lower side of the pressing portion 122A, from the outer peripheral surface of the fit-together portion 124 and has a wall surface that faces in the horizontal direction.

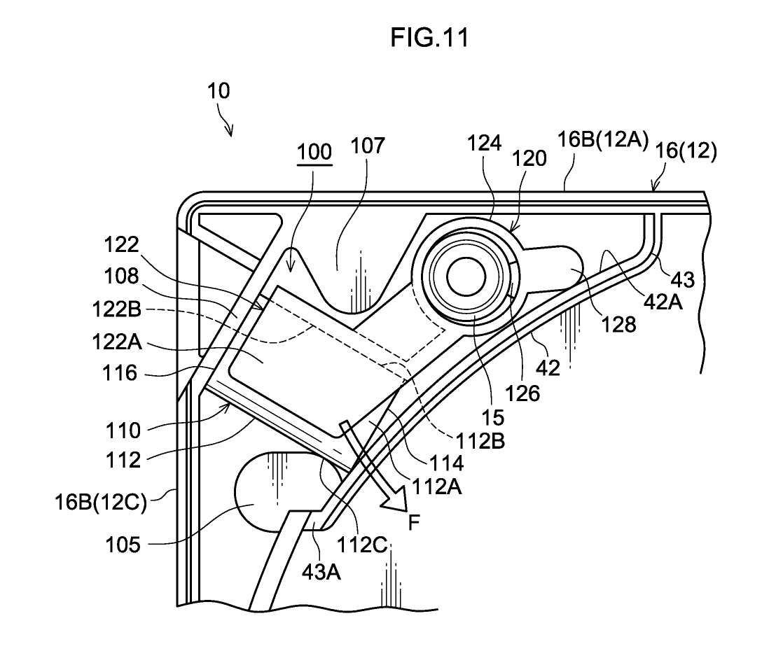

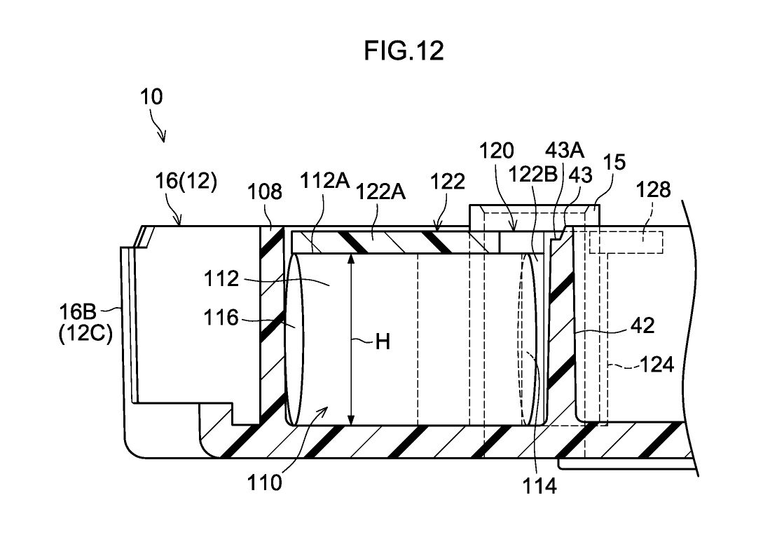

Note that, as shown in FIG. 8 and FIG. 11, a length D in the extending direction of the pressing portion 122A is desirably longer than the radius of the security tag 110, but it does not matter if it is shorter than the diameter. Further, it does not matter if a width W, that is orthogonal to the length D of the pressing portion 122A, is shorter than the length of the security tag 110. Similarly, it does not matter if the width W of the pushing portion 122B as well is shorter than the length of the security tag 110, but a height H of the pushing portion 122B is desirably substantially the same as the diameter of the security tag 110 as shown in FIG. 12.

Further, a rib 128, that is shaped as a tongue piece (the distal end thereof is circular-arc-shaped) and that serves as an anchor portion, is provided to project integrally at the top end portion at the outer peripheral surface of the fit-together portion 124, at the side opposite the pressing portion 122A. At the time of assembling the holding member 120 into the setting space 100 of the lower case 16 in which the security tag 110 is set, this rib 128 anchors an outer peripheral surface 42A of the play restricting wall 42 that serves as an anchored portion within this setting space 100.

Namely, when this rib 128 anchors the outer peripheral surface 42A of the play restricting wall 42, due to the reaction caused by the rib 128 pushing the outer peripheral surface 42A of this play restricting wall 42, urging force that directs the holding portion 122 toward the central side of the reel 20 around the screw boss 15 (in the direction of arrow F in FIG. 11) can be generated at the holding member 120. Accordingly, as described later, the security tag 110 can be pressed by this urging force, and, due thereto, rotation of the holding member 120 around the screw boss 15 can be rendered impossible (the holding member 120 can be fixed).

Here, as shown in FIG. 10 and FIG. 11, the security tag 110 is disposed laterally within the setting space 100 at the front left corner portion of the lower case 16 (is disposed such that the axial center P is directed in a direction orthogonal to the axial direction of the reel 20). Accordingly, when the fit-together portion 124 of the holding member 120 is insertingly-fit with the screw boss 15, the pressing portion 122A of the holding portion 122 presses, from the upper side, an upper surface portion 112A at a peripheral surface 112 of this security tag 110, and restricts movement of this security tag 110 in the upward direction (the height direction).

Then, due to the above-described urging force, the pushing portion 122B of the holding portion 122 presses, from the lateral side, a side surface portion 112B at the peripheral surface 112 of the security tag 110, and hits a portion of a side surface portion 112C, that is 180° opposite this side surface portion 112B, against the bag portion 105 that serves as a first wall portion, and hits (a portion of) the peripheral edge portion of one bottom surface 114 of the security tag 110 against the outer peripheral surface 42A of the play restricting wall 42 that serves as a second wall portion within the setting space 100, and restricts movement of this security tag 110 in the horizontal direction.

Namely, this security tag 110 is held at one point (actually, a line that runs along the axial direction of the security tag 110) by the pressing portion 122A of the holding portion 122, and, in plan view (as seen from the axial direction of the reel 20), is held at three points (actually, a line and planes) by the pushing portion 122B of the holding portion 122, the bag portion 105 and the play restricting wall 42, and play within the setting space 100 is prevented.

Accordingly, damage due to such play is prevented, and the security tag 110 is positioned accurately and held within the setting space 100 of the case 12. Note that, at this time, there may be a state in which a gap is formed, or may be a state in which a gap is not formed, between another bottom surface 116 of the security tag 110 and the inner surface of the standing wall 108.

Further, when the rib 128 is anchored at the outer peripheral surface 42A of the play restricting wall 42 and the holding member 120 is fixed, the dimensions of the top surface (the pressing portion 122A and the rib 128) of the holding member 120 and the security tag 110 are appropriately set so as to, as shown in FIG. 12, not project-out upwardly more than the distal end surfaces (top end surfaces) of the respective wall portions of the peripheral wall 16B, the play restricting wall 42, the jutting-out wall portion 107, the standing wall 108 and the like that structure the setting space 100 of the lower case 16, i.e., so as to be disposed at a lower position (a lower level) than the respective distal end surfaces in side view.

Accordingly, at the time of placing the upper case 14 on the lower case 16 and assembling the case 12, there is no fear that this holding member 120 and security tag 110 will interfere with the peripheral wall portion 14B of the upper case 14, the play restricting wall 42 and the like that are the upper side of the setting space 100. Namely, there is no fear that the holding member 120 and the security tag 110 will be bitten-in between the upper case 14 and the lower case 16.

Note that, in the case of the case 12 that is structured such that stepped portions 43 are formed respectively at the distal end portions of the play restricting wall 42 of the upper case 14 and the play restricting wall 42 of the lower case 16, and the respective step portions 43 mesh with one another when the upper case 14 is placed on the lower case 16 and the play restricting walls 42 are hit against one another, it is desirable that the dimensions thereof be set appropriately such that the top surface of the holding member 120 and the security tag 110 are disposed at a lower position (a lower level) than a hit-against surface 43A that is the lower distal end surface of this stepped portion 43.

Further, the “holding” in the present embodiment means restricting movement in at least two directions that are the upward direction and the horizontal direction. Moreover, for example, polyethylene (PE), polypropylene (PP), polystyrene (PS), polyacetal (POM), polycarbonate (PC) and the like are given as examples of the resin material of which the holding member 120 is molded.

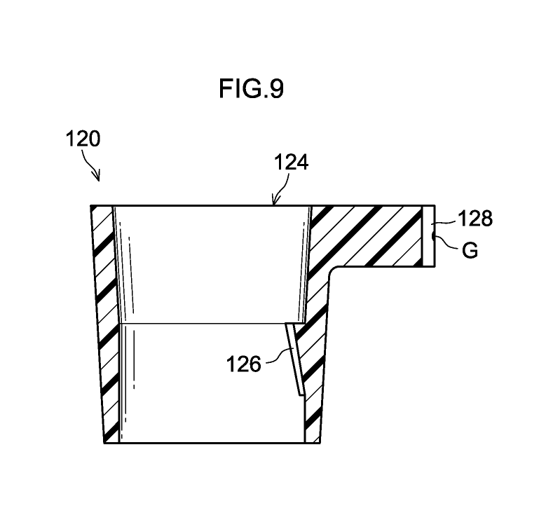

Moreover, as shown in FIG. 6 and FIG. 9, a gate trace G is formed at the distal end of the rib 128 at the substantial center in the height direction. Namely, the gate for the resin material at the time of molding the holding member 120 is made to be the distal end of the rib 128. Here, because the rib 128 is anchored on the play restricting wall 42 and has the function of stopping rotation of the holding member 120, rigidity of a certain extent is needed, and the rib 128 is formed to be thick-walled. Accordingly, when the distal end of this rib 128 is made to be the gate position and a resin material is injected in therefrom, the resin pressure at the time of molding the holding member 120 is transmitted easily, and the dimensional accuracy of the holding member 120 can be improved.

Operation of the recording tape cartridge 10 that is structured as described above is described next. At times of non-use (at times of storage or at times of transport or the like), the opening 18 of the recording tape cartridge 10 is closed by the door 50. Further, due to the urging force of the compression coil spring 98, the braking member 80 is positioned at the rotation-locked position, and the braking gear 84 is made to mesh-together with the engaging gears 48. Therefore, rotation of the reel 20 with respect to the case 12 is impeded.

On the other hand, when the recording tape T is to be used, the recording tape cartridge 10 is loaded into a drive device along the direction of arrow A with the front wall 12A leading. Thus, first, the opening/closing member provided at this drive device side engages with the convex portion 56 of the door 50. Then, in this state, when the recording tape cartridge 10 moves further in the direction of arrow A, the opening/closing member moves the convex portion 56 relatively rearward against the urging force of the coil spring 58.

Thus, the door 50, at which the convex portion 56 is provided so as to project, slides rearward within the groove portions 64 along the right wall 12B, and opens the opening 18. Further, at this time, the position restricting member provided in the drive device engages with the recess 106 formed in the front wall 12A of the case 12 (the lower case 16). Due thereto, the position (depth) of the recording tape cartridge 10 in the loading direction is restricted.

When the recording tape cartridge 10 is loaded to a predetermined depth in the drive device and the opening 18 is completely opened in this way, the recording tape cartridge 10 is lowered a predetermined height, and the positioning members of the drive device are inserted into the holes 102, 104 for positioning that are formed in the lower case 16. Due thereto, the recording tape cartridge 10 is accurately positioned at a predetermined position within the drive device, and further sliding (rearward movement) of the door 50 is restricted.

Further, due to this operation of the recording tape cartridge 10 being lowered, the rotating shaft relatively enters-in from the gear opening 40 and causes the driving gear to mesh with the reel gear 44. Thus, accompanying the operation of this driving gear meshing-together with the reel gear 44, the leg portions 94 that project above the reel gear 44 are pushed-up against the urging force of the compression coil spring 98, the braking member 80 is pushed-up via the releasing member 90, and the meshing of the braking gear 84 and the engaging gears 48 is released.

Then, in the state in which the driving gear and the reel gear 44 are completely meshed-together, due to the reel plate 46 being attracted to/held by the magnetic force of the annular magnet provided at the radial direction inner side of the driving gear, the reel 20 is set in a locking released state in which relative rotation thereof with respect to the case 12 becomes possible within the case 12, while the meshing of the reel gear 44 with the driving gear is maintained.

On the other hand, the pull-out member provided at the drive device side enters into the case 12 from the opening 18 that has been opened, and grasps and pulls-out the leader pin 30 that is positioned and held at the pin holding portions 36. Note that, at this time, because the recording tape cartridge 10 is positioned accurately within the drive device, the pull-out member can reliably cause the hooks thereof to anchor on the annular grooves 32 of the leader pin 30. Further, because the rotation-locked state of the reel 20 is released, the reel 20 can rotate accompanying the operation of pulling-out operation of the leader pin 30.

The leader pin 30, that is pulled-out from the opening 18 in this way, is accommodated at an unillustrated take-up reel. Then, due to this take-up reel and the reel 20 being driven and rotated synchronously, the recording tape T is pulled-out successively from the case 12 while being taken-up onto the take-up reel, and recording or playback of information is carried out by a recording/playback head (not illustrated) that is disposed along a predetermined tape path.

When the recording tape cartridge 10, for which recording or playback of information is finished, is to be discharged from the drive device, first, due to the rotating shaft rotating reversely, the recording tape T is rewound onto the reel 20. Then, when the recording tape T has been rewound to the end thereof onto the reel 20 and the leader pin 30 is held at the pin holding portions 36, the recording tape cartridge 10 is raised a predetermined height, the positioning members are pulled-out from the holes 102, 104 for positioning, the rotating shaft is pulled-out from the gear opening 40, and the meshing-together of the driving gear with the reel gear 44 is cancelled.

Thus, due to the urging force of the compression coil spring 98, the braking member 80 and the releasing member 90 are pushed downward, the leg portions 94 are inserted-through the through-holes 28A and project-out a predetermined height above the reel gear 44 from the bottom surface of the bottom wall 28, and the braking gear 84 meshes-together with the engaging gears 48. Due thereto, the reel 20 is again set in a rotation locked state in which relative rotation thereof within the case 12 is impeded. Thereafter, the recording tape cartridge 10 is moved in the direction opposite the direction of arrow A by an unillustrated ejecting mechanism.

Thus, accompanying this movement, the door 50 slides in the direction of closing the opening 18 due to the urging force of the coil spring 58, and completely closes the opening 18 (returns to the initial state). The recording tape cartridge 10, at which the relative rotation of the reel 20 with respect to the case 12 is locked and the opening 18 is closed in this way, is completely ejected from the interior of the drive device.

Here, if the recording tape cartridge 10 that is ejected from the interior of this drive device is transported-out from a predetermined security area, an alarm sound is issued, and this transporting-out is prevented. Namely, the security tag 110, that can transmit and receive to and from the exterior, is provided within the case 12 of the recording tape cartridge 10.

Accordingly, when the recording tape cartridge 10 passes-through the security gate provided at the entrance/exit of the security area, radio waves are transmitted and received between the emitting antenna and receiving antenna that are provided at this security gate, and the security tag 110, and the transporting of the recording tape cartridge 10 out of the security area is sensed. Accordingly, if an alarm sound is generated, for example, from the security gate due to this sensing, theft or inadvertent taking-out (transporting-out) of the recording tape cartridge 10 from the security area can be psychologically prevented.

Further, this security tag 110 is set such that the axial center P is not perpendicular to the bottom plate 16A of the lower case 16. More concretely, this security tag 110 is disposed laterally so as to be substantially parallel to the bottom plate 16A of the lower case 16.

Accordingly, even if the case 12 of the recording tape cartridge 10 is stacked in the vertical direction (height direction) with the case 12 of the other recording tape cartridge 10, the axial centers P of the respective security tags 110 do not overlap one another, and magnetic coupling does not arise at the respective security tags 110. Accordingly, the communication performances at the respective security tags 110 do not deteriorate.

Still further, this security tag 110 is disposed laterally such that, in plan view, the axial center P is not perpendicular to the peripheral wall 16B of the lower case 16 (the axial center P is not orthogonal to the front wall 12A and the left wall 12C of the case 12).

Accordingly, even if the case 12 of the recording tape cartridge 10 is lined-up adjacent to the case 12 of the other recording tape cartridge 10 with the front walls 12A and the rear walls 12D, or with the left walls 12C and the right walls 12B, aligned, the axial centers P of the respective security tags 110 do not overlap one another, and magnetic coupling does not arise at the respective security tags 110. Accordingly, in this case as well, the communication performances at the respective security tags 110 do not deteriorate.

Further, in the state in which the fit-together portion 124 of the holding member 120 is insertingly-fit (fit-together) with the screw boss 15 by press-fitting, this security tag 110 is pressed from the upper side by the pressing portion 122A of the holding portion 122, and the rib 128 is anchored on the play restricting wall 42, and, due thereto, the security tag 110 is pressed from the lateral side (is hit against the bag portion 105 and the play restricting wall 42) by the pushing portion 122B of the holding portion 122 that is urged in the direction of arrow F (see FIG. 11).

Namely, movement of this security tag 110 in the upward direction and the horizontal direction is restricted by the holding member 120, whose rotation is stopped so as to be unable to rotate around the screw boss 15, and, in this state, the security tag 110 is positioned and held (fixed) within the setting space 100 of the lower case 16. Accordingly, this security tag 110 does not move with play within the setting space 100, and damage due to such play is prevented.

Further, in terms of the structure of the recording tape cartridge 10, the screw boss 15 and the bag portion 105 (the hole 104) are regions having high dimensional accuracy. Accordingly, due to the fit-together portion 124 of the holding member 120 being insertingly-fit (fit-together) with the screw boss 15 and the security tag 110 being hit against the bag portion 105 by the pushing portion 122B of the holding portion 122, the disposed position of the security tag 110 within the case 12 can be stabilized accurately.

Accordingly, the communication performance (communication accuracy) between the security tag 110 and the emitting antenna and the receiving antenna that are provided at the security gate can be improved, and, when the recording tape cartridge 10 passes through the security gate, this passing-through can be reliably sensed.

Further, the fit-together portion 124 of the holding member 120 is made to be a structure that is fit-in (press-fit), from above, with respect to the screw boss 15 that is provided to project at the inner surface of the bottom plate 16A of the lower case 16. The holding portion 122 of the holding member 120 as well is made to be a structure that presses the security tag 110 from the upper side (the upper surface portion 112A side) and the lateral side (the side surface portion 112B side) that faces the screw boss 15.

Accordingly, in the state in which the security tag 110 is placed within the setting space 100 of the lower case 16, this holding member 120 can be installed from above, that is the direction of fitting-together of the fit-together portion 124, so as to press this security tag 110. Accordingly, the ability to assemble the security tag 110 and the holding member 120 into the case 12 (into the setting space 100 of the lower case 16) can be improved.

Further, because the top surface (the pressing portion 122A and the rib 128) of the holding member 120 is disposed at a lower level in side view than the distal end surfaces (top end surfaces) of the respective wall portions that are the peripheral wall 16B of the lower case 16, the play restricting wall 42, the jutting-out wall portion 107, the standing wall 108 and the like, there is no fear that this holding member 120 and security tag 110 will be bitten-in between the upper case 14 and the lower case 16 at the time of assembling the case 12. Accordingly, the assemblability of the recording tape cartridge 10 (the case 12) can be improved, and there is no adverse affect on the communication performance of the security tag 110.

Moreover, as described above, the pressing portion 122A and the pushing portion 122B of the holding portion 122 contact the peripheral surface 112 of the security tag 110 only from two directions that are orthogonal to one another (only the upper surface portion 112A and the side surface portion 112B). Accordingly, even if the size (the length or the diameter) of the security tag 110 is changed in order to improve the communication performance, such design changes can be addressed. Namely, because the holding member 120 has few limitations with respect to the dimensions and shape of the security tag 110, the degrees of freedom in design of the security tag 110 can be improved.

Further, as described above, this holding portion 122 covers only the upper surface portion 112A and the side surface portion 112B at the peripheral surface 112 of the security tag 110 and does not cover other regions, and therefore, the volume is smaller than accommodating containers of the prior art, and less of the resin material that is used suffices as compared with those accommodating containers. Accordingly, the manufacturing cost of the holding member 120 itself can be reduced, and as a result, the manufacturing cost of the recording tape cartridge 10 can be reduced.

Still further, with such a holding structure, even if the dimensional accuracy of the holding portion 122 (the pressing portion 122A and the pushing portion 122B) varies, this holding portion 122 (the pressing portion 122A and the pushing portion 122B) can certainly be made to contact (press-contact) the peripheral surface 112 (the upper surface portion 112A and the side surface portion 112B) of the security tag 110. Accordingly, the assemblability (installability) of the holding member 120 with respect to the security tag 110 is not impaired.

Moreover, because this holding member 120 is a structure that fixes the security tag 110 in cooperation with the case 12, and concretely, is a structure that fixes the security tag 110 with respect to the lower case 16 by pushing the security tag 110 toward the bag portion 105 and the play restricting wall 42, even if the width of the setting space 100 at the front left corner portion of the lower case 16 is changed for example, the security tag 110 can be positioned and held provided that there are the screw boss 15 and the bag portion 105 and the play restricting wall 42. Namely, in accordance with the holding member 120 of such a structure, the security tag 110 can be held within the case 12 without being affected by design changes of the case 12 also.

Further, because the holding member 120 that holds the security tag 110 is a structure that is provided as a body separate from the case 12, there is no need to form, at the case 12 (the upper case 14 and the lower case 16), a holding structure that holds the security tag 110. Accordingly, there is no need to change the design of the mold for injection molding the case 12 (the upper case 14 and the lower case 16), and an increase in the manufacturing cost due thereto can be prevented.

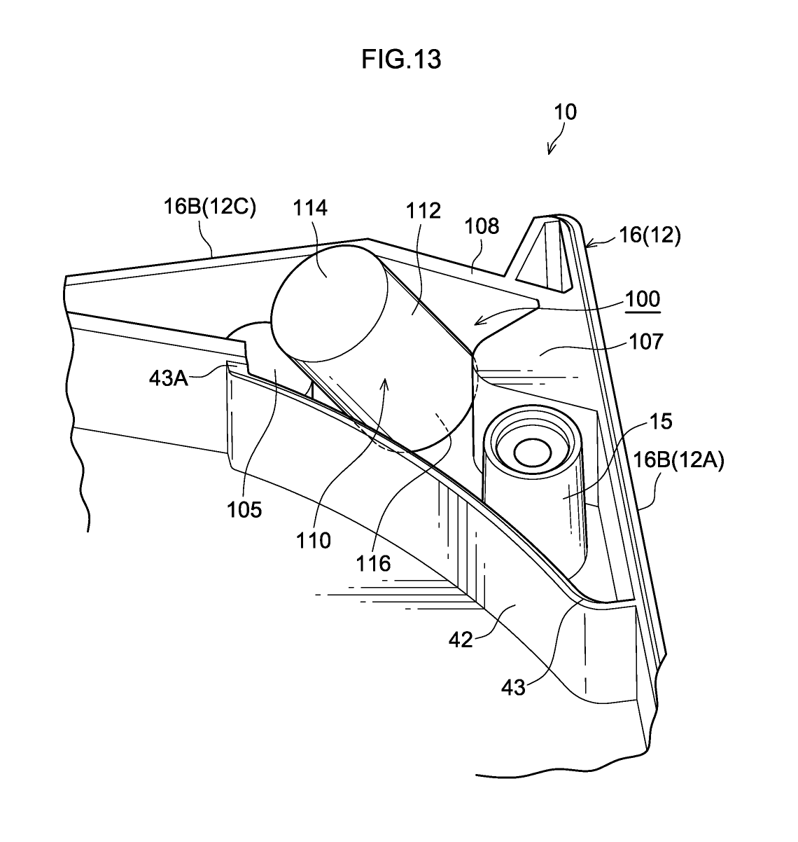

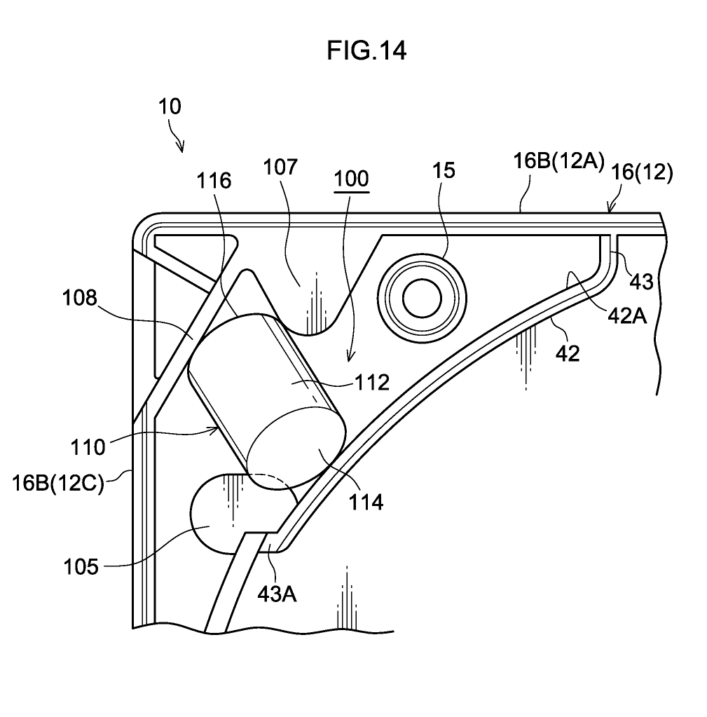

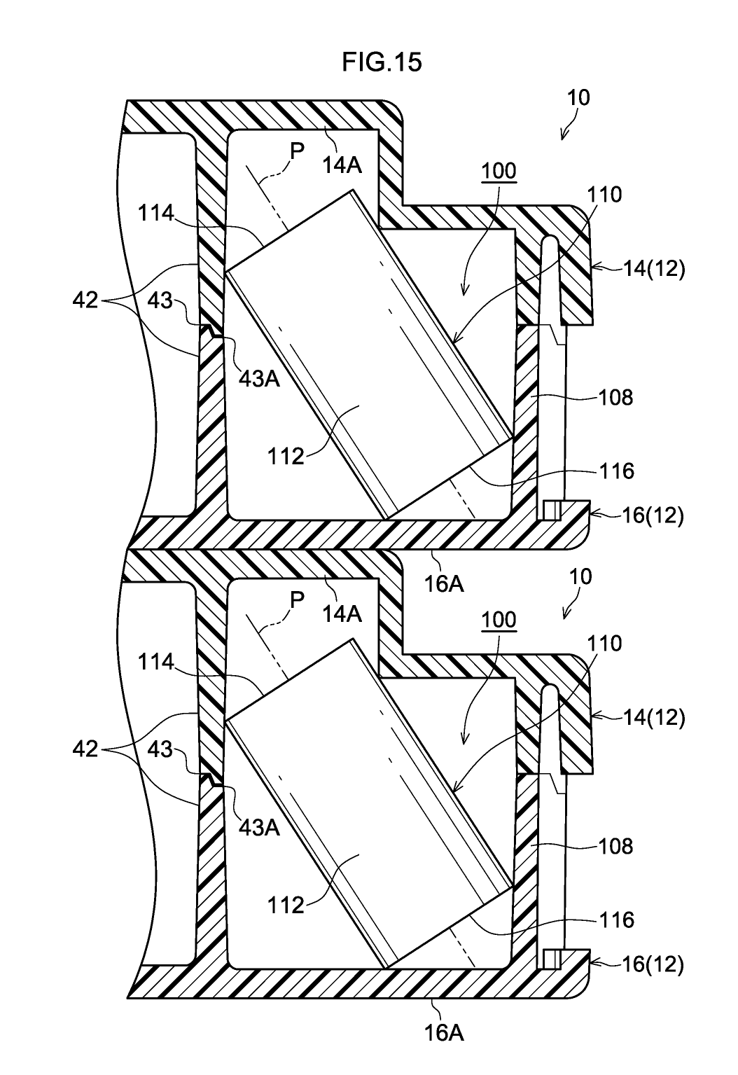

The recording tape cartridge 10 relating to the present embodiment has been described above, but the recording tape cartridge 10 relating to the present embodiment is not limited to the respective illustrated examples, and the design thereof can be changed appropriately within a scope that does not deviate from the gist of the present invention. For example, as shown in FIG. 13 and FIG. 14, the security tag 110 may be structured so as to be set within the setting space 100 such that the axial center P thereof (shown by the imaginary line in FIG. 15) is, in side view, at an incline with respect to the vertical direction (is not perpendicular to the bottom plate 16A of the lower case 16).

In this case, the length of the security tag 110 is made to be longer than that shown in FIG. 4 and FIG. 5, and (portions of) the peripheral edge portion of the other bottom surface 116 are supported by the bottom plate 16A of the lower case 16, the jutting-out wall portion 107 and the standing wall 108, and it suffices for (a portion of) the peripheral edge portion of the one bottom surface 114 or a portion of the peripheral surface 112 to be supported by the play restricting wall 42.

When the security tag 110 (the axial center P) is held at an incline with respect to the vertical direction in side view in this way, the length thereof can be made to be longer than that shown in FIG. 4 and FIG. 5. Therefore, the communication performance can be improved, and, even if the case 12 of the recording tape cartridge 10 is stacked in the vertical direction (the height direction) with the case 12 of the other recording tape cartridge 10 as shown in FIG. 15, it can be made such that the axial centers P of the respective security tags 110 do not overlap one another.

Namely, in this case as well, it can be made such that magnetic coupling does not arise at the respective security tags 110, and therefore, the communication performances do not deteriorate at the respective security tags 110. Further, in this case, even if the case 12 of the recording tape cartridge 10 is lined-up adjacent to the case 12 of the other recording tape cartridge 10 with the front walls 12A and the rear walls 12D, or with the left walls 12C and the right walls 12B, aligned, the axial centers P of the respective security tags 110 do not overlap one another.

Accordingly, magnetic coupling does not arise at the respective security tags 110, and the communication performances do not deteriorate at the respective security tags 110. However, it is preferable that the respective security tags 110 be set such that, as shown in FIG. 14, in plan view (as seen from the axial direction of the reel 20), the axial center P is not perpendicular to the peripheral wall 16B of the lower case 16 (the axial center P is not orthogonal to the front wall 12A and the left wall 12C of the case 12).

Moreover, there may be a structure in which the security tag 110, that is disposed at an incline in this way, is held by appropriately changing the design of the shape of the holding member 120. Further, the pushing portion 122B of the holding portion 122, that presses the security tag 110 from the lateral side (the horizontal direction) in cooperation with the case 12, is not limited to the illustrated one point (plane), and may be two or more points (planes). Moreover, the fitted-together portion is not limited to the screw boss 15, and may be a protrusion (not illustrated) that is provided to protrude in a convex shape at the inner surface of the bottom plate 16A of the lower case 16, or the like.

Further, in order to psychologically prevent the transporting of the recording tape cartridge 10 out from a security area, the recording tape cartridge 10 may be made such that it can be visually distinguished that the recording tape cartridge 10 is the recording tape cartridge 10 in which the security tag 110 is incorporated. Namely, for example, characters such as “Security” or the like may be printed on the ceiling surface of the case 12 (the outer surface of the ceiling plate 14A of the upper case 14), or a recess (not shown) or the like for identification may be formed at the bottom surface of the case 12 (the outer surface of the bottom plate 16A of the lower case 16).

Moreover, the setting space 100 may be formed at the upper case 14 side and not at the lower case 16 side. Namely, there may be a structure in which the security tag 110 and the holding member 120 are provided at the upper case 14 side. Further, although description is given in the present embodiment of the recording tape cartridge 10 for data backup in which the reel 20 is singly accommodated within the case 12, the present invention can be applied also to recording tape cassettes for video taping, or the like, in which two reels are accommodated within a case.

Further, it suffices for the recording tape T that is wound on the reel 20 to be understood as an elongated, tape-shaped information recording/playback medium on which information can be recorded and from which recorded information can be played-back. It goes without saying that the recording tape cartridge 10 that accommodates the reel 20 can also be applied to recording tapes T of any recording/playback formats. Moreover, the entirety of the disclosure of Japanese Patent Application NO. 2010-59947 is cited by reference in the present Description.

### DESCRIPTION OF THE REFERENCE NUMERALS

10 recording tape cartridge
12 case
14 upper case
15 screw boss (fitted-together portion)
16 lower case
16A bottom plate
16B peripheral wall
20 reel
30 leader pin
42 play restricting wall
100 setting space
105 bag portion
108 standing wall
110 security tag
112 peripheral surface
114 bottom surface
116 bottom surface
120 holding member
122 holding portion
122A pressing portion
122B pushing portion
124 fit-together portion
126 jutting-out portion
128 rib
P axial center
T recording tape

1. A recording tape cartridge comprising:
a case that accommodates a reel on which a recording tape is wound; and
a security tag that is provided within the case and can transmit and receive to and from an exterior,
wherein the security tag is made to be a columnar shape having a coil that is formed by a wire material being wound around an outer peripheral surface of a magnetic core, and is set within the case such that, when the case is stacked with a case of another recording tape cartridge, an axial center thereof does not overlap with that of a security tag within the case of the other recording tape cartridge.

2. The recording tape cartridge of claim 1, wherein the security tag is set such that the axial center is not perpendicular to a bottom plate of the case.

3. The recording tape cartridge of claim 1, wherein the security tag is set such that the axial center is substantially parallel to a bottom plate of the case.

4. The recording tape cartridge of claim 1, wherein the security tag is set such that the axial center is not perpendicular to a peripheral wall of the case, as seen from an axial direction of the reel.

5. The recording tape cartridge of claim 1, comprising: a holding member that is provided within the case, and at whose one end side is formed a holding portion that, in cooperation with the case, holds the security tag from an axial direction of the reel and a direction orthogonal to the axial direction; and a fitted-together portion that is formed within the case, and with which a fit-together portion, that is formed at another end side of the holding member, is fit-together.

6. The recording tape cartridge of claim 5, wherein the holding member is formed so as to be able to be installed within the case, in a state in which the security tag is provided within the case.

7. A recording tape cartridge comprising:
a case that is substantially rectangular and that accommodates a reel on which a recording tape is wound; and
a security tag that is provided within the case and can transmit to and receive from an exterior,
wherein the security tag is made to be a columnar shape having a coil that is formed by a wire material being wound around an outer peripheral surface of a magnetic core, and is set within the case such that, when the case is lined-up adjacent to a case of another recording tape cartridge with front and rear, or left and right, peripheral walls being aligned, an axial center thereof does not overlap with that of a security tag within the case of the other recording tape cartridge.
